(19) United States
(12) Patent Application Publication
(10) Pub. No.: US 2021/0316627 A1
(43) Pub. Date: Oct. 14, 2021

(54) RE-CHARGING SYSTEM OF A VEHICLE AND RELATED METHOD

(71) Applicant: GREEN BUSINESS S.R.L., VASTO CHIETI (IT)

(72) Inventor: Pietro Di Foglio, Bologna (IT)

(21) Appl. No.: 17/272,504

(22) PCT Filed: Aug. 26, 2019
(86) PCT No.: PCT/IT2019/000065

§ 371 Date: Mar. 1, 2021

(30) Foreign Application Priority Data
Aug. 28, 2018 (IT) 102018000008196

(51) Int. Cl. B60L 53/31; H02J 3/38; H02J 7/35; F21S 9/03; B60L 53/51; B60L 53/30; B60L 53/302

(52) U.S. Cl. CPC B60L 53/31; H02J 3/381; H02J 7/35; F21S 9/035; H01L 35/28; B60L 53/305; B60L 53/302; H02J 2300/24; H02J 2310/48; B60L 53/51

(57) ABSTRACT

A system (1) is described, for electrically re-charging a vehicle (20) through a plurality of energy devices connected to an inverter (10) of the system (1) and through a public electric mains (5) connected to the system (1) through a lighting means (2); every energy device comprises: a first photovoltaic generator, equipped with a plurality of photovoltaic modules (6) electrically supplied by at least one accumulating means (4); a second photovoltaic generator, equipped with a photovoltaic layer (22); a piezoelectric device designed to transform mechanical energy generated by a passage of the vehicle (20) into electric energy; and a thermo-electric generator (8) arranged on the accumulating means (4). A method for re-charging a vehicle (20) is also described.

### CROSS-REFERENCE TO RELATED APPLICATIONS

The present Utility patent application claims priority benefit of the Italian patent number 102018000008196, filed on Aug. 28, 2018 under 35 U.S.C. 119(a). The present Utility patent application is the National Phase filing under 35 U.S.C. 371 of the International Application No PCT/IT2019/000065 filed Aug. 26, 2019 entitled “RE-CHARGING SYSTEM OF A VEHICLE AND RELATED METHOD”. The contents of these related Italian and PCT applications are incorporated herein by reference for all purposes to the extent that such subject matter is not inconsistent herewith or limiting hereof.

### FIELD OF THE INVENTION

The present invention refers to a re-charging system of a vehicle, in particular to an electrically re-charging system. The present invention further refers to a method for re-charging a vehicle.

A plurality of fixed re-charging stations for electric vehicles are known in the art, shaped as small columns, and four re-charging modes for light-weight vehicles are also known: a re-charge occurs in alternate current through a domestic or industrial plug, and lacks any protection or any communication with the vehicle; or through a protecting device integrated in the re-charging cable, regulating the power and monitoring the safety parameters; or through the connection of the vehicle to a fixed re-charging station, which performs the functions of differential and magneto-thermal protection, and of managing an enablement and suitable safety locks; or through the connection of the vehicle to a fixed direct current re-charging station. Such fixed re-charging stations cannot be easily located by a user and the related use modes do not include a vehicle detecting and identifying system.

The need of reducing energy consumptions is known, together with providing efficient electrically re-charging systems by exploiting renewable energy sources.

It is further clear that no fixed re-charging stations are known which are connected to and supplied by a plurality of energy devices, also integrated in the electric lighting mains.

Object of the present invention is solving the above prior art problems, by providing a system and a method for re-charging a vehicle through a plurality of energy devices.

Another object of the present invention is providing a re-charging system of a vehicle integrated in the public electric mains, capable of supplying the vehicle and of providing electric energy to the public electric mains.

A further object of the present invention is providing a system capable of supplying a continuous service for electrically re-charging a vehicle.

The above and other objects and advantages of the invention, as will result from the following description, are obtained with a system and a method for re-charging a vehicle as claimed in the respective independent claims. Preferred embodiments and non-trivial variations of the present invention are the subject matter of the dependent claims.

It is intended that all enclosed claims are an integral part of the present description.

It will be immediately obvious that numerous variations and modifications (for example related to shape, sizes, arrangements and parts with equivalent functionalities) can be made to what is described, without departing from the scope of the invention as appears from the enclosed claims.

### BRIEF DESCRIPTION OF THE DRAWINGS

The present invention will be better described by some preferred embodiments thereof, provided as a non-limiting example, with reference to the enclosed drawings, in which:

FIG. 1 shows a perspective view of a preferred embodiment of the system according to the present invention;

FIG. 2 shows a schematic representation of the operation of the system according to the present invention;

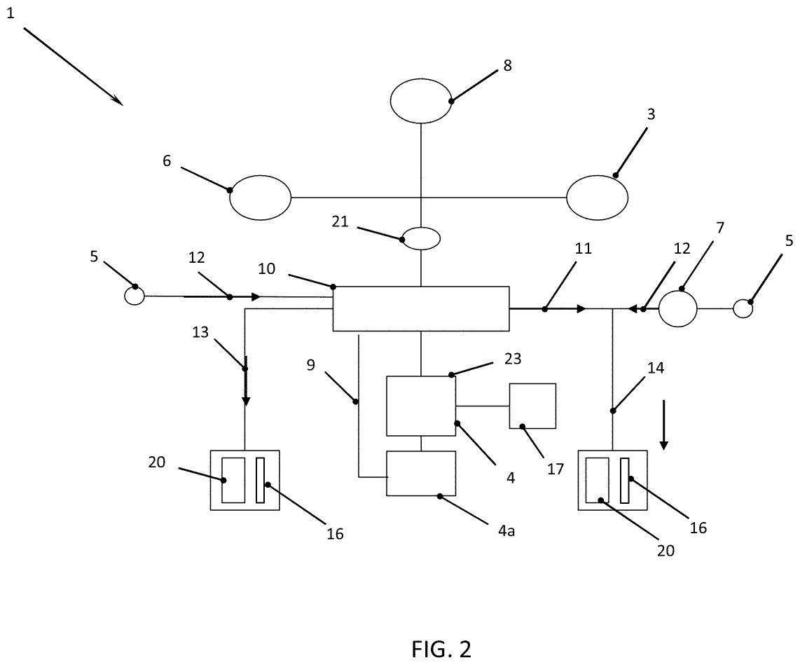

FIG. 3 shows a sectional view of a preferred embodiment of a component of the system according to the present invention; and

FIGS. 4-6 show a perspective view of a preferred embodiment for fastening a plurality of photovoltaic elements on a component of the system according to the present invention.

### DETAILED DESCRIPTION

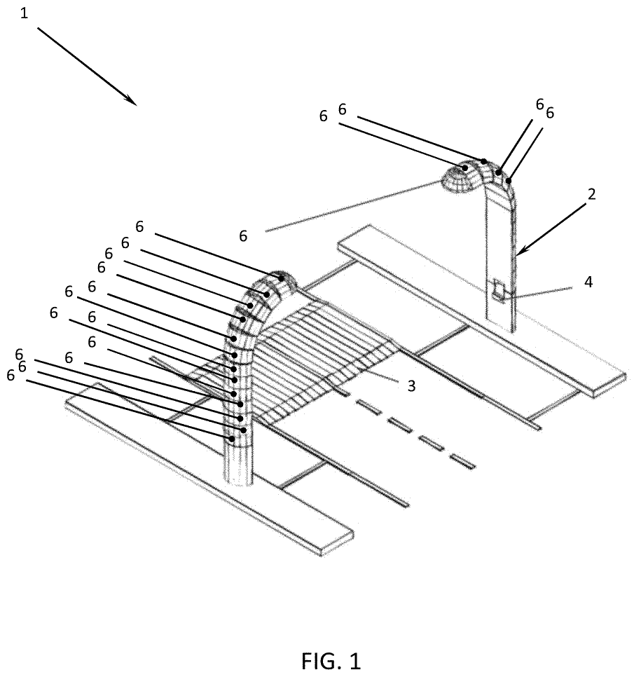

With reference to FIG. 1, a re-charging system 1 according to the present invention is designed to supply electric energy to a vehicle 20, such as, for example, a means of transport with tires and electric traction, through a plurality of energy devices connected to at least one inverter 10 of the system 1 and through a public electric mains 5 connected to the system 1 through at least one lighting means 2; the system 1 comprises:

the inverter 10, such as, for example, a hybrid bi-directional inverter, arranged in the lower portion of the lighting means 2, and equipped with at least one charge regulator, such as for example a maximum power point tracking (MPPT), designed to receive electric energy produced by the plurality of energy devices through at least one direct current meter 21, and to supply electric energy, regulated and maximized through the charge regulator, directly to the vehicle 20 using the system 1, and/or to accumulating means 4 of electric energy, such as, for example, a lithium battery, and/or to the public electric mains 5 through at least one single input meter 7; and

the plurality of energy devices connected to the inverter 10 of the system 1 through a physical support, such as an electric cable, or through communicating means with radiofrequency waves, such as, for example, a Wi-Fi connection.

Advantageously, the plurality of energy devices comprise:

a first photovoltaic generator, arranged on the external surface of the lighting means 2, such as for example a street lamp, integrated in the public electric mains 5, such photovoltaic generator being equipped with a plurality of photovoltaic modules 6, such as, for example, plexi-glass photovoltaic modules, equipped with photovoltaic cells encapsulated in the stratigraphy itself and/or a hollow space, or in the plexi-glass edges, and/or nano-structured through luminescent solar concentrators (LSC), or equipped with spherical solar cells, allowing to optimize the functionality of the photovoltaic generator, conferring light-weight to the lighting means 2 and making them visible by the user, even under scarce visibility situations, or also photovoltaic modules composed of a plurality of cells on flexible, or semi-flexible laminates, or amorphous, or poly-crystalline, or mono-crystalline thin films, and electrically supplied by the accumulating means 4;

the electric energy accumulating means 4, such as, for example a lithium or graphene battery, preferably with 30 kWp, arranged in the lower portion of the lighting means 2, equipped with at least one interface means 4a, such as, for example, a touch-screen, designed to allow the user to perform 9 a plurality of actions and services related to the delivery of electric energy from the system 1, such as, for example, choice of the type of payment, of the alternate or direct re-charging modes, etc.;

a second photovoltaic generator, arranged on the upper surface of at least one road bollard 3, equipped with a photovoltaic layer 22, designed to guarantee a time re-charge continuity of the vehicle 20 preferably in a time range of 4 hours;

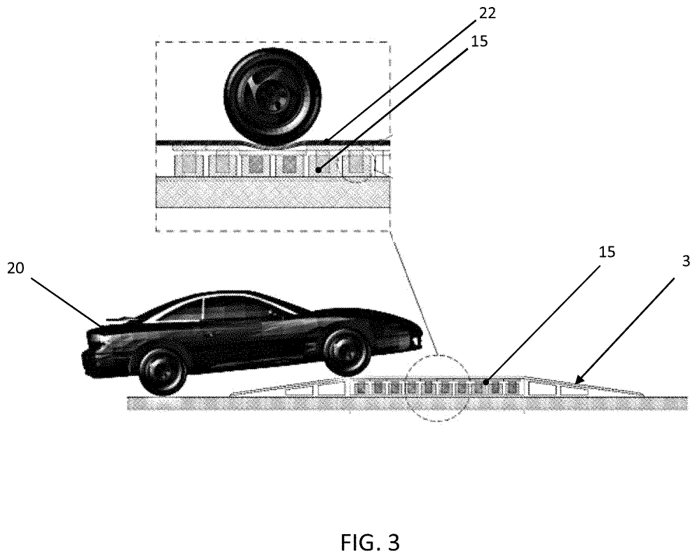

at least one piezoelectric device, arranged, as shown in FIG. 3, inside the road bollard 3, such as, for example, a road bump, preferably with a global length of about 620 cm, fastened to the road surface through a plurality of fastening means, and equipped with a layered structure 15 adapted to contain therein mechanical and/or kinetic piezoelectric elements, and/or piezoelectric films, and designed to transform mechanical energy generated by the passage of the vehicle 20 on the road bollard 3 into electric energy; and

at least one thermo-electric generator 8, arranged on the accumulating means 4, such as for example a semiconductor device, equipped with a plurality of Seebeck cells designed to directly transform a heat flow into electric energy, and with a plurality of Peltier cells designed to supply a cooling process simultaneously with the thermo-electric production of the plurality of Seebeck cells, enabling a suitable cooling of the accumulating means 4.

Advantageously, the system 1 is integrated and connected to the public electric mains 5, through the lighting means 2, such public electric mains 5 being designed for:

distributing alternate and direct current electric energy to public lighting plants;

receiving from the inverter 10 an amount of excess electric energy produced by the plurality of energy devices and supplying it to at least one lighting means 2, allowing an optimization and energy savings for managing the daily and nightly electric supply of the public electric mains 5; and

providing, through a digital transmitting device, upon need, electric energy necessary to complete the re-charging of a vehicle 20, in direct current mode 13 or alternate current mode 14, depending on at least one request by the user through the interface means 4a.

The system 1 is also equipped with containing means arranged in the lower portion of the lighting means 2 and designed to contain therein the accumulating means 4 and the thermo-electric generator, while the interface means 4a and at least one connecting device, such as for example an electric connector, are arranged on the external surface, to enable the connection of the vehicle 20 with the system 1, allowing its electric re-charge.

Moreover, the system 1 is designed to supply a plurality of public utility services 16, such as, for example, road lighting, LED lighting, or safety TV cameras, or parking ticket office, or 4G/5G mobile service, or Wi-Fi connection, or mobile phones signal repeater, or real-time information about traffic conditions, reducing the use of fossil sources and the distribution of electric energy by the public electric mains 5.

Advantageously, the lighting means 2, as shown in FIG. 1, have a curved and aerodynamic shape, allowing an optimum coating of the upper, front and side surfaces of the lighting means 2 with the plurality of transparent or semi-transparent photovoltaic modules 6, equipped with photovoltaic cells, whose thickness is preferably few microns, and preferably arranged on the upper surface of the lighting means 2, being suited to the curved front and upper surfaces of the lighting means 2, allowing to increase and maximize the capturing surface, and of capturing and recycling natural and artificial lights, and giving a contribution to the supply of the plurality of services 16, even in a blackout situation. Moreover, such plurality of photovoltaic modules 6 are advantageously composed of photovoltaic films equipped with a Internet-Of-Things, IOT, technology, allowing to identify, connect and locate the lighting means 2 and giving it a capability of processing data and of interacting with external environments.

Moreover, the lighting means 2 are equipped with piezoelectric sensors having reduced sizes, arranged on the external surface of the lighting means 2 and connected to the interface means 4a and to at least one emergency unit 17 equipped with a plurality of electric energy accumulators, such as, for example, supercapacitors, arranged inside the lighting means 2. It is clear how the lighting means 2 enable to house a plurality of components, allowing to insert further components, or optimized components, such as, for example, dimensionally increased accumulating means 4.

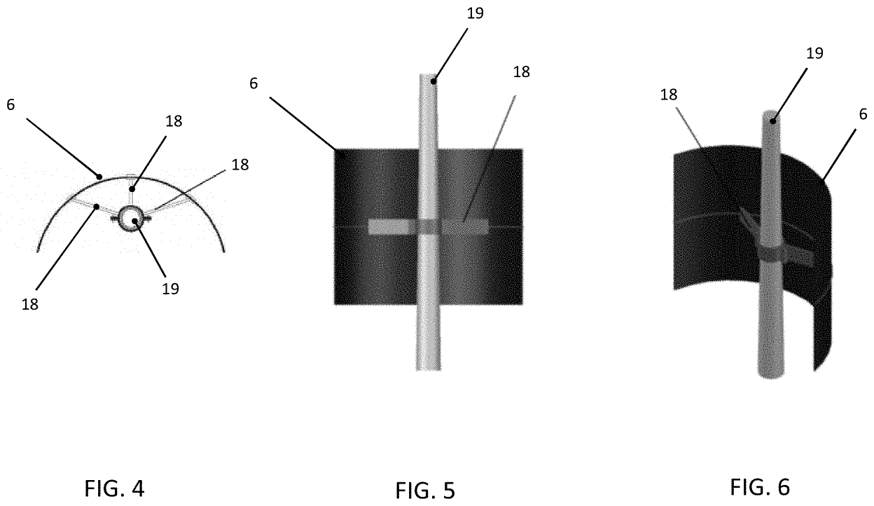

Moreover, as shown in FIGS. 4, 5, 6 as a non-limiting example, a preferred fastening mode is shown for the plurality of photovoltaic modules 6 on the lighting means 2, through a plurality of fastening elements 18, such as, for example brackets, designed to enable the fastening of such plurality of photovoltaic modules 6 on the external surface of the supporting element 19, such as, for example a pole, of the lighting means 2, equipped on its top with the communication means with radio-frequency waves.

Finally, the system 1 is also equipped with a hardware and software infrastructure, such as, for example a digital platform, designed to detect and identify the vehicle 20 and to supply a plurality of information to the user, such as, for example, location of the system 1, charge status, system availability, payment mode, etc. through a dedicated web application arranged on a mobile device of the user.

An electric apparatus is also described, equipped with two or more systems 1 according to the present invention, mutually connected through communication means with radio-frequency waves, optimizing the management of the electric supply of the daily and nightly public electric mains 5.

The invention further deals with a method for re-charging a vehicle 20, through the re-charging system 1, such method comprising the steps of:

providing and identifying the system 1 by a user through the infrastructure of the system 1;

producing electric energy by the plurality of energy devices;

transferring electric energy produced by the plurality of energy devices to the inverter 10;

sending electric energy and delivering 23 electric energy by the inverter 10 for storing electric energy in the accumulating means 4;

if the system 1 receives a re-charging request from the user, before the complete storage of electric energy in the accumulating means 4, the inverter 10 stops the delivery 23 of electric energy and supplies electric energy directly to the user vehicle 20, in a direct current mode 13 or in an alternate current mode 14, depending on at least one request by the user through the interface means 4a; and

if the system 1 receives a re-charging request from the user, before the complete storage of electric energy in the accumulating means 4 and the electric energy supplied by the inverter 10 to vehicle 20 is not enough to complete the re-charging of the vehicle 20, the public electric mains 5 supplies 12 electric energy necessary to complete the re-charging of the vehicle 20.

What is claimed is:

1. A system (1) for electrically re-charging at least one vehicle (20), characterized in that the system (1) is designed to supply at least one electric re-charge to said vehicle (20) through a plurality of energy devices connected to at least one inverter (10) of said system (1) and through a public electric mains (5) connected to said system (1) through at least one lighting means (2), said plurality of energy devices being composed of:
a first photovoltaic generator, arranged on an external surface of said lighting means (2), integrated and connected to said public electric mains (5), equipped with a plurality of photovoltaic modules (6) electrically supplied by at least one accumulating means (4);
said accumulating means (4) of electric energy, arranged in a lower portion of said lighting means (2);
a second photovoltaic generator, arranged on an upper surface of at least one road bollard (3), equipped with a photovoltaic layer (22), designed to guarantee a time re-charge continuity of said vehicle (20);
at least one piezoelectric device, arranged on said road bollard (3), fastened to the road surface through a plurality of fastening means, and equipped with a layered structure (15) adapted to contain therein piezoelectric elements, designed to transform mechanical energy generated by a passage of said vehicle (20) on said road bollard (3) into electric energy; and
at least one thermo-electric generator (8) arranged on the accumulating means (4).

2. The system (1) according to claim 1, characterized in that it further comprises:
said inverter (10), arranged in the lower portion of said lighting means (2), and equipped with at least one charge regulator, designed for receiving electric energy produced by said plurality of energy devices through at least one direct current meter (21), and to supply electric energy, regulated and maximized through said charge regulator, directly to at least one vehicle (20) using said system (1), and/or to said accumulating means (4) of electric energy, and/or to a public electric mains (5) through at least one single input meter (7); and
said plurality of energy devices connected to said inverter (10) of said system (1) through at least one physical support, or through communication means with radio-frequency waves.

3. The system (1) according to claim 1, characterized in that said thermo-electric generator (8) is equipped with a plurality of Seebeck cells designed to directly transform a heat flow into electric energy, and with a plurality of Peltier cells designed to supply a cooling process simultaneously with said thermo-electric production of said plurality of Seebeck cells, enabling an adequate cooling of said accumulating means (4).

4. The system (1) according to claim 1, characterized in that said public electric mains (5), is designed for:
distributing electric energy in alternate and direct current to public lighting plants;
receiving from said inverter (10) an amount of excess electric energy produced by said plurality of energy devices and supplying it to said lighting means (2), optimizing a management of the electric supply of said daily and nightly public electric mains (5); and
supplying, upon need, electric energy, through at least one digital transmitting device, necessary for completing said re-charging of said vehicle (20), in a direct current mode (13) or in an alternate current mode (14), depending on at least one request by said user, through at least one interface means (4a) of said accumulating means (4) designed to allow said user to perform (9) a plurality of actions and services related to said re-charging of electric energy of said vehicle (20) by said system (1).

5. The system (1) according to claim 1, characterized in that said lighting means (2) are equipped with a plurality of piezoelectric sensors arranged on an external surface of said lighting means (2) and connected to said interface means (4a) and to at least one emergency unit (17) equipped with a plurality of electric energy accumulators, arranged inside said lighting means (2).

6. The system (1) according to claim 1, characterized in that said lighting means (2) have a curved and aerodynamic shape, equipped with said plurality of photovoltaic modules (6) designed to provide an optimum coating of said upper surface of said lighting means (2) allowing to increase and maximize a capturing surface, and of capturing and recycling natural and artificial light, and providing a contribution to the supply of a plurality of public utility services (16), said plurality of photovoltaic modules (6) being composed of photovoltaic films equipped with Internet-Of-Things, IOT, technology, enabling to identify, connect and locate said lighting means (2), and conferring them a capability of processing data and interacting with external environments.

7. The system (1) according to claim 1, characterized in that said plurality of photovoltaic modules (6) are fastened on said lighting means (2), through a plurality of fastening elements (18), designed to enable a fastening of said plurality of photovoltaic modules (6) on an external surface of at least one supporting element (19) of said lighting means (2).

8. The system (1) according to claim 1, characterized in that it is equipped with containing means arranged in said lower portion of said lighting means (2) and designed to contain therein said accumulating means (4) and said thermo-electric generator, while said interface means (4a) and at least one connecting device are arranged on the external surface, enabling a connection of said vehicle (20) with said system (1), allowing said electric re-charging.

9. An electric apparatus equipped with two or more systems (1) for electrically re-charging at least one vehicle (20), characterized in that said two or more of said systems (1) are mutually connected through communication means with radio-frequency waves, optimizing a management of said electric supply of said daily and nightly public electric mains (5).

10. A method for re-charging a vehicle (20) through a system (1) for electrically re-charging at least one vehicle (20), characterized in that it comprises the steps of:
providing and identifying said system (1) by said user through at least one infrastructure of said system (1) designed to supply a plurality of information to said user, through a dedicated web application arranged on at least one mobile device of said user;
producing electric energy by said plurality of energy devices;
transferring electric energy produced by said plurality of energy devices to said inverter (10);
sending electric energy and delivering (23) electric energy by said inverter (10) for storing electric energy in said accumulating means (4);
if said system (1) receives a request for re-charging from said user, before a complete storage of electric energy in said accumulating means (4), said inverter (10) stops said delivery (23) of electric energy and supplies electric energy directly to said vehicle (20) of said user, in a direct current mode (13) or in an alternate current mode (14) depending on said request by said user through said interface means (4a); and
if said system (1) receives a request of re-charging from said user, before said complete storage of electric energy in said accumulating means (4), and the electric energy supplied by said inverter (10) to said vehicle (20) is not enough to complete said re-charging of said vehicle (20), said public electric mains (5) supplies (12) electric energy necessary for said completion of said re-charging of said vehicle (20).
